(19) United States
(12) Patent Application Publication
(10) Pub. No.: US 2023/0164900 A1
(43) Pub. Date: May 25, 2023

(54) APPARATUS FOR AND METHOD OF ACCELERATING DROPLETS IN A DROPLET GENERATOR FOR AN EUV SOURCE

(71) Applicant: ASML Netherlands B.V., Veldhoven (NL)

(72) Inventors: Alexander Igorevich Ershov, Escondido, CA (US); Chirag Rajyaguru, San Diego, CA (US); Dietmar Uwe Herbert Trees, San Diego, CA (US); Joshua Mark Lukens, San Diego, CA (US); Theodorus Wilhelmus Driessen, San Diego, CA (US); Robert Jay Rafac, Encinitas, CA (US); Georgiy Olegovich Vaschenko, San Diego, CA (US)

(21) Appl. No.: 18/011,593

(22) PCT Filed: Jun. 21, 2021
(86) PCT No.: PCT/EP2021/066798

§ 371 Date: Dec. 20, 2022

Related U.S. Application Data
(60) Provisional application No. 63/045,354, filed on Jun. 29, 2020.

(51) Int. Cl. H05G 2/00

(52) U.S. Cl. CPC H05G 2/006; H05G 2/008; G03F 7/70033

(57) ABSTRACT

Apparatus for and method of accelerating droplets used to generate EUV radiation that comprise an arrangement producing a laser beam directed to an irradiation region and a droplet source. The droplet source includes a fluid exiting a nozzle in a stream that breaks up into droplets that then undergo coalescence. The droplets are then subjected to a stream of gas that entrains and accelerates the droplets.

### CROSS REFERENCE TO RELATED APPLICATIONS

This application claims priority to U.S. Application No. 63/045,354, filed Jun. 29, 2020, titled APPARATUS FOR AND METHOD OF ACCELERATING DROPLETS IN A DROPLET GENERATOR FOR AN EUV SOURCE, and which is incorporated herein in its entirety by reference.

### FIELD

The present application relates to extreme ultraviolet (“EUV”) light sources and their methods of operation. These light sources provide EUV light by creating plasma from a source or target material. In one application, the EUV light may be collected and used in a photolithography process to produce semiconductor integrated circuits.

### BACKGROUND

A patterned beam of EUV light can be used to expose a resist coated substrate, such as a silicon wafer, to produce extremely small features in or on the substrate. Extreme ultraviolet light (also sometimes referred to as soft x-rays) is generally defined as electromagnetic radiation having wavelengths in the range of about 5-100 nm. One particular wavelength of interest for photolithography occurs at 13.5 nm.

Methods to produce EUV light include, but are not necessarily limited to, converting a source material into a plasma state that has a chemical element with an emission line in the EUV range. These elements can include, but are not necessarily limited to, xenon, lithium and tin.

In one such method, often termed laser produced plasma (“LPP”), the desired plasma can be produced by irradiating a source material, for example, in the form of a droplet, stream or wire, with a laser beam. In another method, often termed discharge produced plasma (“DPP”), the required plasma can be generated by positioning source material having an appropriate emission line between a pair of electrodes and causing an electrical discharge to occur between the electrodes.

One technique for generating droplets involves melting a target or source material such as tin and then forcing the liquid tin under high pressure through a relatively small diameter orifice, such as an orifice having a diameter of about 0.5 μm to about 30 μm, to produce a stream of droplets. Under most conditions, in a process called Rayleigh breakup, naturally occurring instabilities, e.g. noise, in the stream exiting the orifice, will cause the stream to break up into microdroplets. These droplets may have varying velocities and may combine with each other as they travel in the stream to coalesce into larger droplets.

The task of the droplet generator is to place droplets in the primary focus of a collector mirror where they will be used as fuel for the EUV production. The droplets must arrive at primary focus within certain spatial and temporal stability criteria, that is, with position and timing that is repeatable within acceptable margins. They must also arrive at a given frequency and velocity. Furthermore, the droplets must be fully coalesced, meaning that the droplets must be monodisperse (of uniform size) and arrive at the given drive frequency.

An increasing need for high EUV power at high repetition rates drives requirements for higher speed droplets with much higher droplet spacing. Acceleration of the droplets generated by a droplet generator has been achieved in the past by increasing the driving gas pressure. Currently, pressures on the order of 4000 psi (270 Bar) are used to achieve droplet velocities of about 82 m/sec. Future EUV designs call for much higher velocities, that will require drive pressures of up to 15000 psi (1000 Bar) to achieve. There is a limit, however, to how much droplet velocity can be increased by increasing the driving gas pressure. Using such high pressures presents a number of problems, including but not limited to materials performance and stability at these pressures, an increase in droplet coalescence length at higher pressures, safety, regulatory requirements, etc. Also, fluid flow in the orifice could become turbulent at a given fluid velocity and nozzle geometry, causing droplet instability.

Gas acceleration of the droplets generated by a droplet generator has been considered as a way to increase droplet velocities without having to increase the driving gas pressure. For example, U.S. Pat. No. 8,598,551, titled “EUV Radiation Source Comprising a Droplet Accelerator and Lithographic Apparatus”, naming Mestrom et al. as inventors, and issued Dec. 3, 2013, which is hereby incorporated by reference in its entirety, discloses an EUV radiation source that includes a droplet accelerator configured to accelerate the fuel droplets using gas. The use of an accelerating gas, if not implemented properly, however, can introduce instabilities into the droplet stream.

There is thus a need to be able to accelerate droplets in a manner that does not require high drive gas pressures and limits any tendency for an accelerating gas to destabilize the droplet stream.

### SUMMARY

The following presents a simplified summary of one or more embodiments in order to provide a basic understanding of the embodiments. This summary is not an extensive overview of all contemplated embodiments and is not intended to identify key or critical elements of all embodiments nor delineate the scope of any or all embodiments. Its sole purpose is to present some concepts of one or more embodiments in a simplified form as a prelude to the more detailed description that is presented later.

According to one aspect of an embodiment, there is provided a droplet generator in which droplets are not exposed to the flow of accelerating gas in the initial portion of the stream in which the droplets are still coalescing to their final size. This “droplet coalescence zone,” is thus characterized by an absence of any substantial gas flow which would interfere with the ability of the droplet to reach full coalescence.

According to another aspect of an embodiment, an accelerating gas is used to entrain and accelerate the droplets after they have left the droplet coalescence zone. The accelerating gas is accelerated gradually to the maximum value thus limiting disturbances in the gas flow.

According to another aspect of an embodiment, the maximum value of the gas flow is below the speed of sound for the gas at the temperature and pressure of the gas. According to other aspects of other embodiments, the maximum value of the gas flow is the same as or above the speed of sound for the gas at the temperature and pressure of the gas

According to another aspect of an embodiment, the incoming gas flow is thermalized, that is, caused to attain thermal equilibrium with the droplet generator to avoid thermal shocks when the gas is introduced into the gas acceleration zone of the droplet generator.

According to another aspect of an embodiment, the velocity of the gas flowing into the accelerator near the end of the droplet coalescence zone is matched to the velocity of droplets leaving the droplet coalescence zone.

According to one aspect of an embodiment, there is disclosed a droplet generator for generating a stream of droplets of EUV source material, the droplet generator comprising a nozzle adapted to emit a stream of liquid EUV source material from a nozzle outlet, a first structure defining a droplet coalescence zone, extending downstream from the nozzle outlet to a first location, in which the stream of liquid EUV source material breaks up and coalesces into a stream of coalesced droplets of liquid EUV source material, at least one inlet adapted to be connected to a source of a gas, and a second structure defining a gas acceleration zone, extending downstream from the first location to a second location, in fluid communication with the at least one inlet, arranged to receive the stream of coalesced droplets at the first location, and adapted to cause the gas to be introduced into the gas acceleration zone downstream of the first location and to accelerate and flow streamwise substantially parallel to the stream of coalesced droplets to entrain the coalesced droplets, the droplet coalescence zone being arranged and configured such that liquid EUV source material in the droplet coalescence zone is not exposed to a streamwise flow of the gas. The streamwise length of the droplet coalescence zone may be between 10 mm and 200 mm, or between 20 mm and 200 mm. Here and elsewhere, the term “may” connotes that what follows is one of several possibilities.

The gas acceleration zone may have a round cross section having an internal cross-sectional area that decreases between the first location and the second location. The gas acceleration zone may have an internal circular cross section having a radius that decreases between the first location and the second location. The gas acceleration zone may be configured so that a streamwise velocity of the gas does not exceed the speed of sound for the gas. The gas acceleration zone may be configured so that a streamwise velocity of the gas at the second location is approximately but less than the speed of sound for the gas. The gas acceleration zone may be configured so that a streamwise velocity of the gas at the first location is approximately equal to a streamwise velocity of the coalesced droplets leaving the droplet coalescence zone at the first location. The gas may accelerate the coalesced droplets gas such that coalesced droplets entering the gas acceleration zone at the first location accelerate from about 80 m/sec to about 130 m/sec while traversing the gas acceleration zone to the second location.

The droplet generator may further comprise a thermalizing structure arranged to be in thermal contact with the gas and adapted to thermalize the gas to attain thermal equilibrium with the droplet generator before the gas is introduced into the gas acceleration zone. The thermalizing structure may be adapted to heat the gas to a temperature between 200° C. and 300° C. The droplet generator may further comprise a source material heater arranged to supply heat to the source material in the droplet generator and the thermalizing structure is arranged transfer heat between the source material heater and the gas. The gas may be a gas having a low EUV absorption, for example, hydrogen. At least one of the first structure and second structure may comprise a refractory metal which may, for example, be at least one of molybdenum, tungsten, tantalum, and rhenium and their alloys. At least one of the first structure and second structure may comprise a boron nitride coating.

According to another aspect of an embodiment, there is disclosed a method of accelerating droplets of EUV source material, the method comprising emitting a stream of liquid EUV source material from a nozzle outlet of a droplet generator, transforming the stream of liquid EUV source material into a stream of coalesced droplets in a first structure defining a droplet coalescence zone, extending downstream from the nozzle outlet to a first location, introducing the stream of coalesced droplets at the first location into a second structure defining a gas acceleration zone extending downstream from the first location to a second location, introducing a flow of gas into the gas acceleration zone to flow streamwise substantially parallel to the stream of coalesced droplets, accelerating the flow of gas in the gas acceleration zone as the gas approaches the second location, and entraining the coalesced droplets in the flow of gas to accelerate the coalesced droplets, the droplet coalescence zone being arranged and configured such that liquid EUV source material in the droplet coalescence zone is not exposed to a streamwise flow of the gas. The streamwise length of the droplet coalescence zone may be between 10 mm and 200 mm. The streamwise length of the droplet coalescence zone may be between 20 mm and 100 mm.

The gas acceleration zone may have a round cross section having a cross-sectional area that decreases between the first location and the second location. The gas acceleration zone may have a circular internal cross section having a radius that decreases between the first location and the second location. Accelerating the flow of gas in the gas acceleration zone may comprise accelerating the gas so that a streamwise velocity of the gas does not exceed the speed of sound for the gas. Accelerating the flow of gas in the gas acceleration zone may comprise accelerating the gas so that a streamwise velocity of the gas at the second location is approximately but less than the speed of sound for the gas. Introducing a flow of gas into the gas acceleration zone may comprise introducing the gas so that a streamwise velocity of the gas at the first location is approximately equal to a streamwise velocity of the coalesced droplets leaving the droplet coalescence zone at the first location. Entraining the coalesced droplets in the flow of gas to accelerate the coalesced droplets may accelerate the coalesced droplets gas such that coalesced droplets entering the gas acceleration zone at the first location accelerate while traversing the gas acceleration zone from about 80 m/sec to about 130 m/sec at the second location.

The method may also include thermalizing the gas to attain thermal equilibrium with the droplet generator before the gas is introduced into the gas acceleration zone. Thermalizing the gas may comprise heating the gas to a temperature between 200° C. and 300° C. The droplet generator may comprise a source material heater arranged to supply heat to the source material in the droplet generator and thermalizing the gas may comprise transferring heat between the source material heater and the gas. The gas may have a low EUV absorption. The gas may comprise hydrogen. At least one of the first structure and second structure may comprise a refractory metal which may be at least one of molybdenum, tungsten, tantalum, and rhenium or one of their alloys. At least one of the first structure and second structure comprises a boron nitride coating.

According to another aspect of an embodiment, there is disclosed a droplet generator for generating a stream of droplets of EUV source material, the droplet generator comprising a nozzle adapted to emit liquid EUV source material from a nozzle outlet, at least one inlet adapted to be connected to a source of a gas, a first structure defining a first zone, extending downstream from the nozzle outlet to a first location, in which the liquid EUV source material emitted by the nozzle is not exposed to a flow of the gas, the EUV source material being in the form of a stream of droplets at the first location, and a second structure defining a gas acceleration zone, extending downstream from the first location to a second location, in fluid communication with the inlet, arranged to receive the stream of droplets at the first location, and adapted to cause the gas to be introduced into the gas acceleration zone downstream of the first location and to accelerate and flow streamwise substantially parallel to the stream of droplets to entrain the droplets.

According to another aspect of an embodiment, there is disclosed a method of accelerating droplets of EUV source material, the method comprising emitting liquid EUV source material from a nozzle outlet of a droplet generator, passing the liquid EUV source material through a first zone extending downstream from the nozzle outlet to a first location; the liquid EUV source material exiting the first zone as a stream of droplets, introducing the stream of droplets at the first location into a gas acceleration zone extending downstream from the first location to a second location, introducing a flow of gas into the gas acceleration zone to flow streamwise substantially parallel to the stream of droplets, accelerating the flow of gas in the gas acceleration zone as the gas approaches the second location, and entraining the droplets in the flow of gas to accelerate the droplets, the first zone being arranged and configured such that liquid EUV source material in the first zone is not exposed to a streamwise flow of the gas.

The droplet generator may further comprise a flow management element positioned downstream of the second location and adapted to manage high velocity gas exiting the gas acceleration zone.

Further embodiments, features, and advantages of the present invention, as well as the structure and operation of the various embodiments are described in detail below with reference to accompanying drawings.

### BRIEF DESCRIPTION OF THE DRAWINGS

The accompanying drawings, which are incorporated herein and form part of the specification, illustrate the methods and systems of embodiments of the invention by way of example, and not by way of limitation. Together with the detailed description, the drawings further serve to explain the principles of and to enable a person skilled in the relevant art(s) to make and use the methods and systems presented herein. The drawing features are not necessarily to scale. In the drawings, like reference numbers indicate identical or functionally similar elements.

FIG. 1 is a simplified, schematic diagram of an apparatus including an EUV light source having an LPP EUV light radiator.

FIG. 2 is a not-to-scale cross sectional view of a droplet generator illustrating states of coalescence in a droplet stream.

FIG. 3A is a not-to-scale cross sectional diagram of a droplet generation system with a droplet accelerator according to an aspect of an embodiment.

FIG. 3B is an enlargement of a portion of FIG. 3A

FIG. 4 is a plan view of a droplet generation system with a droplet accelerator according to an aspect of an embodiment.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art based on the teachings contained herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details described below. In other instances, well-known structures and devices are shown in block diagram form in order to facilitate description of one or more embodiments. The following presents a simplified summary of one or more embodiments in order to provide a basic understanding of the embodiments. This summary is not an extensive overview of all contemplated embodiments and is not intended to identify key or critical elements of all embodiments nor delineate the scope of any or all embodiments.

Before describing such embodiments in more detail, however, it is instructive to present an example environment in which embodiments of the present invention may be implemented. In the description that follows and in the claims the terms “up,” “down,” “top,” “bottom,” “vertical,” “horizontal,” and like terms may be employed. These terms are intended to show relative orientation only and not any orientation with respect to gravity. Also, in some instances, the terms “upstream”, “downstream” and “streamwise” are used in connection with orientation and position with respect to the droplet stream described below. These terms are intended to have their normal and customary meanings of nearer to the source (or nozzle) for upstream, farther from the source (or nozzle) for downstream, and in the direction of the stream for streamwise.

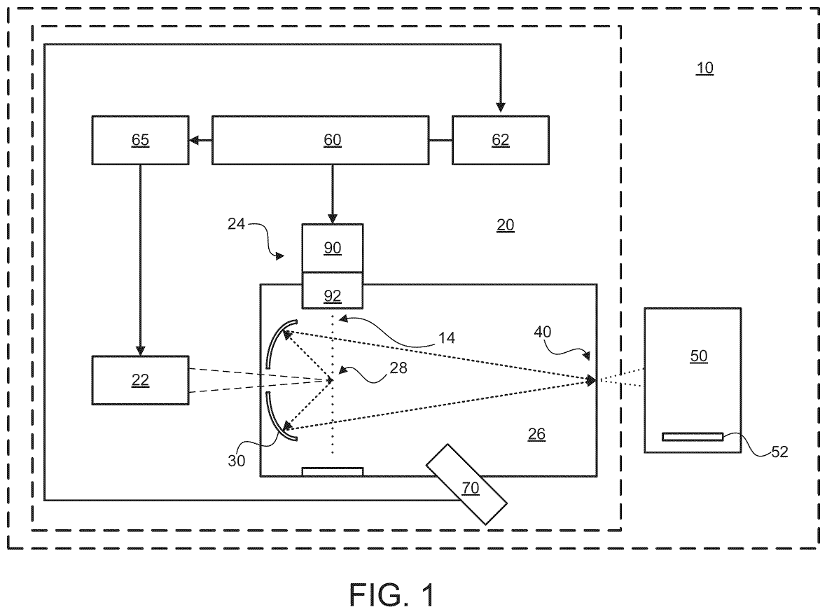

FIG. 1 illustrates a specific example of an apparatus 10 including an EUV light source 20 having an LPP EUV light radiator. As shown, the EUV light source 20 may include a system 22 for generating a train of light pulses and delivering the light pulses into a light source chamber 26. The light pulses may travel along one or more beam paths from the system 22 and into the chamber 26 to illuminate droplets of source material 14 at an irradiation region 28 to produce an EUV light output for exposure of a substrate 52 in an exposure device 50.

Suitable lasers for use in the system 22 shown in FIG. 1 may include a pulsed laser device, e.g., a pulsed gas discharge CO₂ laser device producing radiation at 9.3 μm or 10.6 μm, e.g., with DC or RF excitation, operating at relatively high power, e.g., 10 kW or higher and high pulse repetition rate, e.g., 50 kHz or more. In one particular implementation, the laser may be an axial-flow RF-pumped CO₂ laser having an oscillator-amplifier configuration (e.g., master oscillator/power amplifier (MOPA) or power oscillator/power amplifier (POPA)) with multiple stages of amplification and having a seed pulse that is initiated by a Q-switched oscillator with relatively low energy and high repetition rate, e.g., capable of 100 kHz operation. From the oscillator, the laser pulse may then be amplified, shaped and/or focused before reaching the irradiation region 28. Continuously pumped CO₂ amplifiers may be used for the laser system 22. Alternatively, the laser may be configured as a so-called “self-targeting” laser system in which the droplet serves as one mirror of the optical cavity.

Depending on the application, other types of lasers may also be suitable, e.g., an excimer or molecular fluorine laser operating at high power and high pulse repetition rate. Other suitable examples include a solid state laser, e.g., having a fiber, rod, slab, or disk-shaped active media, other laser architectures having one or more chambers, e.g., an oscillator chamber and one or more amplifying chambers (with the amplifying chambers in parallel or in series), a master oscillator/power oscillator (MOPO) arrangement, a master oscillator/power ring amplifier (MOPRA) arrangement, or a solid state laser that seeds one or more excimer, molecular fluorine or CO₂ amplifier or oscillator chambers. Other designs may be suitable.

In some instances, a source material may first be irradiated by a pre-pulse and thereafter irradiated by a main pulse. Pre-pulse and main pulse seeds may be generated by a single oscillator or two separate oscillators. In some setups, one or more common amplifiers may be used to amplify both the pre-pulse seed and main pulse seed. For other arrangements, separate amplifiers may be used to amplify the pre-pulse and main pulse seeds.

System 22 may include a beam conditioning unit having one or more optics for beam conditioning such as expanding, steering, and/or focusing the beam that reaches the irradiation site 28. For example, a steering system, which may include one or more mirrors, prisms, lenses, etc., may be provided and arranged to steer the laser focal spot to different locations in the chamber 26. The steering system may include a first flat mirror mounted on a tip-tilt actuator which may move the first mirror independently in two dimensions, and a second flat mirror mounted on a tip-tilt actuator which may move the second mirror independently in two dimensions. With this arrangement, the steering system may controllably move the focal spot in directions substantially orthogonal to the direction of beam propagation (beam axis).

As further shown in FIG. 1, the EUV light source 20 may also include a source material delivery system 90 including a droplet source 92, e.g., delivering source material, such as tin droplets, into the interior of chamber 26 to the irradiation region or primary focus 28, where the droplets will interact with light pulses from the system 22, ultimately to produce plasma and generate an EUV emission to expose the substrate 52 such as a resist coated wafer in the exposure device 50. More details regarding various droplet dispenser configurations may be found for example in U.S. Pat. No. 7,872,245, issued on Jan. 18, 2011, titled “Systems and Methods for Target Material Delivery in a Laser Produced Plasma EUV Light Source”, U.S. Pat. No. 7,405,416, issued on Jul. 29, 2008, titled “Method and Apparatus For EUV Plasma Source Target Delivery”, and U.S. Pat. No. 7,372,056, issued on May 13, 2008, titled “LPP EUV Plasma Source Material Target Delivery System”, the contents of each of which are hereby incorporated by reference in their entirety.

The source material for producing an EUV light output for substrate exposure may include, but is not necessarily limited to, a material that includes tin, lithium, xenon or combinations thereof. The EUV emitting element, e.g., tin, lithium, xenon, etc., may be in the form of liquid droplets and/or solid particles contained within liquid droplets. For example, the element tin may be used as pure tin, as a tin compound, e.g., SnBr₄, SnBr₂, SnH₄, as a tin alloy, e.g., tin-gallium alloys, tin-indium alloys, tin-indium-gallium alloys, or a combination thereof. Depending on the material used, the source material may be presented to the irradiation region at various temperatures including room temperature or near room temperature (e.g., tin alloys, SnBr₄), at an elevated temperature, (e.g., pure tin) or at temperatures below room temperature, (e.g., SnH₄), and in some cases, can be relatively volatile, e.g., SnBr₄.

Continuing with reference to FIG. 1, the apparatus 10 may also include an EUV controller 60, which may also include a drive laser control system 65 for controlling devices in the system 22 to thereby generate light pulses for delivery into the chamber 26, and/or for controlling movement of optics in the system 22. The apparatus may also include a droplet position detection system which may include one or more droplet imagers 70 that provide an output indicative of the position of one or more droplets, e.g., relative to the irradiation region 28. The imager(s) 70 may provide this output to a droplet position detection feedback system 62, which can, e.g., compute a droplet position and trajectory, from which a droplet error can be computed, e.g., on a droplet-by-droplet basis, or on average. The droplet error may then be provided as an input to the controller 60, which can, for example, provide a position, direction and/or timing correction signal to the system 22 to control laser trigger timing and/or to control movement of optics in the system 22, e.g., to change the location and/or focal power of the light pulses being delivered to the irradiation region 28 in the chamber 26. Also for the EUV light source 20, the source material delivery system 90 may have a control system operable in response to a signal (which in some implementations may include the droplet error described above, or some quantity derived therefrom) from the controller 60, to e.g., modify the release point, initial droplet stream direction, droplet release timing and/or droplet modulation to correct for errors in the droplets arriving at the desired irradiation region 28.

Continuing with FIG. 1, the apparatus may also include an optic 30 such as a near-normal incidence collector mirror having a reflective surface in the form of a prolate spheroid (i.e., an ellipse rotated about its major axis) having, e.g., a graded multi-layer coating with alternating layers of molybdenum and silicon, and in some cases, one or more high temperature diffusion barrier layers, smoothing layers, capping layers and/or etch stop layers. FIG. 1 shows that the optic 30 may be formed with an aperture to allow the light pulses generated by the system 22 to pass through and reach the irradiation region 28. As shown, the optic 30 may be, e.g., a prolate spheroid mirror that has a first focus within or near the irradiation region 28 and a second focus at a so-called intermediate region 40, where the EUV light may be output from the EUV light source 20 and input to an exposure device 50 utilizing EUV light, e.g., an integrated circuit lithography tool. It is to be appreciated that other optics may be used in place of the prolate spheroid mirror for collecting and directing light to an intermediate location for subsequent delivery to a device utilizing EUV light.

A buffer gas such as hydrogen, helium, argon or combinations thereof, may be introduced into, replenished and/or removed from the chamber 26. The buffer gas may be present in the chamber 26 during plasma discharge and may act to slow plasma created ions to reduce optic degradation and/or increase plasma efficiency. Alternatively, a magnetic field and/or electric field (not shown) may be used alone, or in combination with a buffer gas, to reduce fast ion damage.

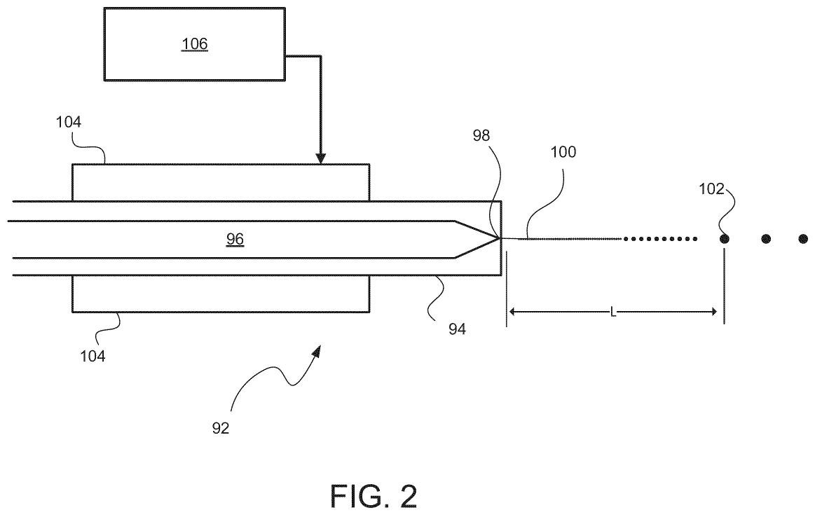

FIG. 2 illustrates the components of a simplified droplet source 92 in schematic format. As shown there, the droplet source 92 may include a capillary 94 holding a fluid 96, e.g. molten tin, under pressure. The capillary may be made of a material such as a glass. Also shown, the capillary 94 may be formed with a nozzle with an end or orifice 98 allowing the pressurized fluid 96 to flow through the nozzle end 98 establishing a continuous stream 100 which subsequently breaks into a plurality of droplets. The droplet source 92 shown further includes a sub-system producing a disturbance in the fluid having an electro-actuatable element 104 that is operably coupled with the fluid 96 and a signal generator 106 driving the electro-actuatable element 104.

The electro-actuatable element 104 produces a disturbance in the fluid 96 which generates droplets having differing initial velocities causing at least some adjacent droplet pairs to coalesce together prior to reaching the irradiation region. The ratio of initial droplets to coalesced droplets may be two, three or more and in some cases tens, hundreds, or more. This is but one system for generating droplets. It will be apparent that other systems may be used such as, for example, systems that create an individual droplet at the nozzle orifice, e.g., for a “droplet on demand” mode in which the gas pressure is sufficient only for the formation of a droplet of target material at the nozzle orifice but is insufficient for the formation of a jet. See U.S. Pat. No. 7,449,703, titled “Method and Apparatus for EUV Plasma Source Target Delivery Target Material Handling”, issued Nov. 11, 2008, the entire disclosure of which is hereby incorporated by reference.

When the target material 96 first exits the nozzle end 98, the target material is in the form of a velocity-perturbed steady stream 100. The stream breaks up into a series of microdroplets having varying velocities. The microdroplets coalesce into droplets of an intermediate size, referred to as subcoalesced droplets, having varying velocities with respect to one another. The subcoalesced droplets coalesce into droplets 102 having the desired final size. The number of coalescence steps can vary. The distance from the nozzle to the point at which the droplets reach their final coalesced state is the coalescence distance L.

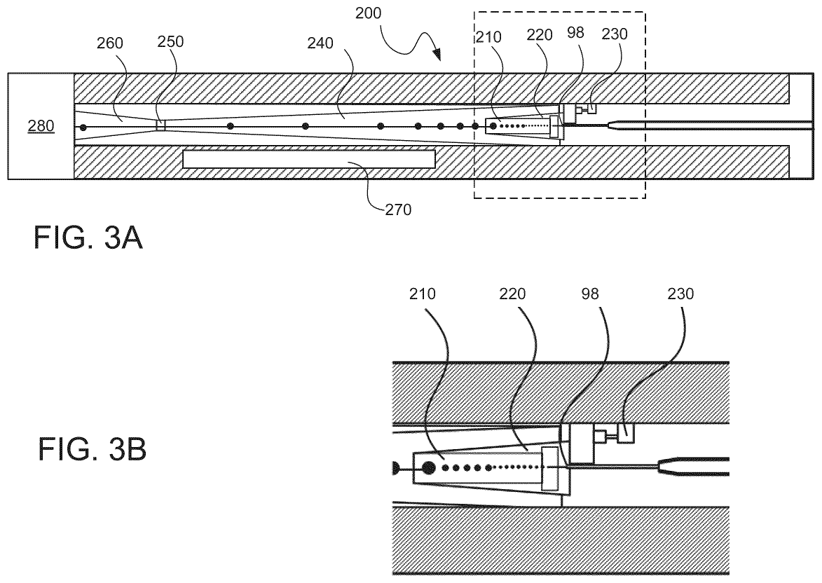

The above description is in terms of specific types of droplet generators for the purpose of a concrete example to simplify the description only. It will be apparent that there are other arrangements for provision of a target material such as Sn to the nozzle and other means of modulation that can be used and to which the teachings herein may be advantageously applied. As mentioned, meeting the future demand for high EUV power at high repetition rates will require higher speed droplets with larger spacing between droplets. Gas acceleration of the droplets generated by a droplet generator has been considered as a way to increase droplet velocities without having to increase the driving gas pressure. The gas must be introduced into the droplet accelerator, however, in a way that does not at the same time introduce unacceptable instabilities into the droplet stream. FIGS. 3A and 3B show a droplet generator/accelerator designed to accelerate the droplets in an acceptable manner, with FIG. 3B being an enlargement of the portion of FIG. 3A in the dashed box. FIGS. 3A and 3B are not to scale; the droplets are much smaller than depicted and are enlarged only to show their location and state of coalescence.

As shown in FIG. 3A, a droplet accelerator 200 includes a droplet coalescence zone 210 downstream of the nozzle end 98. Gas to accelerate the droplets is introduced into the droplet accelerator 200 through an inlet 230. The droplet coalescence zone 210 is protected from the gas by a shroud 220 which establishes the droplet coalescence zone 210. The streamwise length of the droplet coalescence zone 210, that is, the streamwise distance between the nozzle end 98 and the downstream end of the coalescence zone 210, is selected so that the droplets will be fully coalesced before they leave the droplet coalescence zone 210. In other words, the streamwise length of the droplet coalescence zone 210 is selected to be greater than the coalescence length L. Conversely, for a droplet coalescence zone length of a given length the driving waveform may be selected so that the coalescence length is less than the length of the droplet coalescence zone. Protecting the droplets within the droplet coalescence zone 210, especially the smaller subcoalesced droplets and microdroplets, reduces instabilities. This is in part because the smaller droplets are more prone to being deflected laterally because of their smaller mass.

Also shown in FIG. 3A, a gas acceleration zone 240 is configured as a cavity in the droplet accelerator 200 downstream of the droplet coalescence zone 210. The cross sectional area of the gas acceleration zone 240 (that is the internal cross section of the cavity) decreases with streamwise distance from the downstream end of the droplet coalescence zone 210. The cross sectional area of the gas acceleration zone 240 is advantageously made round for some applications and even circular. The interior of the gas acceleration zone 240 is configured according to aspects of other embodiments so that the acceleration of the gas in the gas acceleration zone 240 is constant. It is in general, however, desired to avoid any sharp edges in the cross section and to make the surfaces aerodynamic.

The reduction in cross section of the gas acceleration zone 240 causes the gas in the gas acceleration zone 240 to accelerate. The gas entrains and accelerates the droplets in the gas acceleration zone 240. Downstream of the gas acceleration zone is an orifice 250. Downstream of the orifice 250 is an outlet 260. The gas acceleration zone 240 is the zone in which the droplets start their gas-driven acceleration. It should be noted, however, that the droplets continue to accelerate after they exit gas acceleration zone 240. The gas acceleration zone 240 is primarily the zone where gas is accelerating. In accordance with one aspect of an embodiment it is the only zone where the gas is accelerating. In this gas acceleration zone 240 the gas accelerates and flows streamwise substantially parallel to the stream of coalesced droplets to entrain the coalesced droplets. Substantially parallel in this context means sufficiently parallel that the gas flow does not impart to the droplets any substantial velocity that is transverse to streamwise. Also shown in FIG. 3A is a flow suppression element 280 which may be, for example, a suppressor, skimmer, silencer, muffler, or differentially pumped region to manage high velocity gas exiting the accelerator to limit its effect on other flows present in the source vessel, e.g. those flows which are introduced for collector protection and other source material management.

According to one aspect of an embodiment, the acceleration of the gas in the gas acceleration zone is selected to be gradual so as to avoid introducing instabilities into the droplet flow. By “gradual” here is meant that acceleration is such that the gas accelerates from about 50 m/sec to about 2000 m/sec over the length of the gas acceleration zone 240 which would typically be in the range of 150 millimeters to about 300 millimeters. According to one aspect of an embodiment, the acceleration is selected so that the velocity of the gas does not exceed the speed of sound for that gas at that temperature. According to one aspect of an embodiment, the acceleration is selected so that the final velocity of the gas is approximately but less than, that is almost but not quite, the speed of sound for that gas at that temperature. According to another aspect of an embodiment, the velocity of the gas at the point where it first encounters the droplets downstream of the droplet coalescence zone 210 is selected to be approximately equal to the velocity of the droplets exiting the droplet coalescence zone 210. In this context, about approximately equal to means sufficiently close to the velocity of the droplets that the droplets are not abruptly accelerated upon exposure to the gas flow. For other embodiments the velocity of the gas where it first encounters the droplets downstream of the droplet coalescence zone 210 is selected to less or greater than the velocity of the droplets exiting the droplet coalescence zone 210. The interior of the gas acceleration zone 240 is configured according to aspects of other embodiments so that the acceleration of the gas in the gas acceleration zone 240 is constant.

The gas used to accelerate the droplets should in general be a gas that has a low EUV absorption. One suitable gas is H₂. It will be apparent to those of ordinary skill in the art that other gases, and mixtures of gases, may be used as the gas which accelerates the droplets.

The material used to make the interior surfaces of the droplet coalescence zone 310 and gas acceleration zone 240 are advantageously selected to be resistant to corrosion from the source material, in this example, tin. Suitable materials include refractory metals such as molybdenum, tungsten, tantalum, rhenium, and their alloys. The surfaces may also be provided with coating such as a ceramic material including BN, TiN, SiC, and CrN. If such coating is used, the underlying material of the droplet accelerator can be a more conventional alloy such as stainless steel or a similar material.

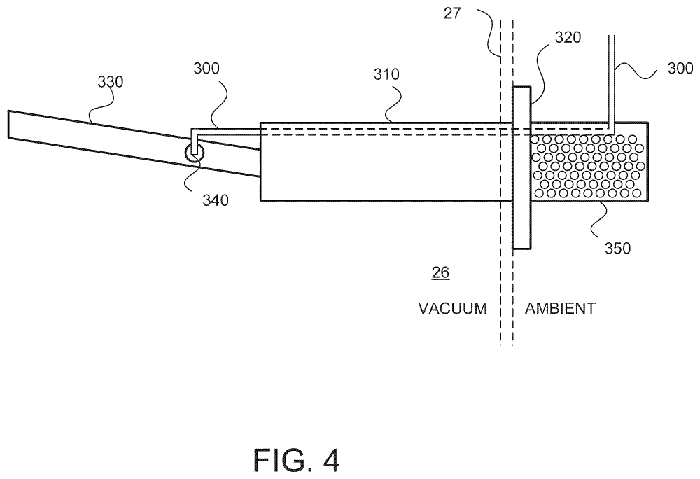

According to another aspect of embodiment, the gas used to accelerate the droplets is thermalized before being introduced into the gas acceleration zone 340. FIG. 4 shows an arrangement for accomplishing this. In FIG. 4, a tube 300 is arranged to receive gas from a gas supply. Tube 300 enters the vacuum chamber 26 through a flange 320 and chamber wall 27 and then is arranged to pass through the body of a droplet generator 310. The droplet generator 310 heats the gas in the tube 300 to the internal temperature of the droplet generator 310 thus thermalizing the gas by bringing the gas in thermal equilibrium with the temperature inside the droplet generator 310. Thermalized gas then enters into a heater block 330 for the droplet generator 310 through an inlet 340. In general, the thermalizing structure is adapted to heat the gas to a temperature between 200° C. and 300° C. but other suitable temperatures may be used. From there the gas is conveyed to a point where it is introduced into the gas acceleration zone 240. Also shown in FIG. 4 is a cage 350 designed to protect high temperature components protruding from the flange 320. As the acceleration gas enters the vacuum in the gas acceleration zone, it expands more or less adiabatically. For some applications it is advantageous to preserve thermalization by providing one or more heaters 270 in the gas accelerator as shown in FIG. 3A to maintain a stable temperature. This stable temperature, for example, may be in the range between 200° C. and 300° C.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance. The breadth and scope of the present invention should not be limited by any of the above-described exemplary embodiments, but should be defined only in accordance with the following claims and their equivalents.

Other aspects of the invention are set out in the following numbered clauses.

1. A droplet generator for generating a stream of droplets of EUV source material, the droplet generator comprising:
a nozzle adapted to emit a stream of liquid EUV source material from a nozzle outlet;
a first structure defining a droplet coalescence zone, extending downstream from the nozzle outlet to a first location, in which the stream of liquid EUV source material breaks up and coalesces into a stream of coalesced droplets of liquid EUV source material;
at least one inlet adapted to be connected to a source of a gas; and
a second structure defining a gas acceleration zone, extending downstream from the first location to a second location, in fluid communication with the at least one inlet, arranged to receive the stream of coalesced droplets at the first location, and adapted to cause the gas to be introduced into the gas acceleration zone downstream of the first location and to accelerate and flow streamwise substantially parallel to the stream of coalesced droplets to entrain the coalesced droplets,
the droplet coalescence zone being arranged and configured such that liquid EUV source material in the droplet coalescence zone is not exposed to a streamwise flow of the gas.
2. A droplet generator as in clause 1 wherein a streamwise length of the droplet coalescence zone is between 10 mm and 200 mm.
3. A droplet generator as in clause 2 wherein a streamwise length of the gas acceleration zone is between 20 mm and 200 mm.
4. A droplet generator as in clause 1 wherein the gas acceleration zone has a round cross section having a cross-sectional area that decreases between the first location and the second location.
5. A droplet generator as in clause 1 wherein the gas acceleration zone has a circular cross section having a radius that decreases between the first location and the second location.
6. A droplet generator as in clause 1 wherein the gas acceleration zone is configured so that a streamwise velocity of the gas does not exceed the speed of sound for the gas.
7. A droplet generator as in clause 1 wherein the gas acceleration zone is configured so that a streamwise velocity of the gas at the second location is approximately but less than the speed of sound for the gas.
8. A droplet generator as in clause 1 wherein the gas acceleration zone is configured so that a streamwise velocity of the gas at the first location is approximately equal to a streamwise velocity of the coalesced droplets leaving the droplet coalescence zone at the first location.
9. A droplet generator as in clause 1 wherein the gas accelerates the coalesced droplets gas such that coalesced droplets entering the gas acceleration zone at the first location accelerate from about 80 m/sec to about 130 m/sec while traversing the gas acceleration zone to the second location.
10. A droplet generator as in clause 1 further comprising a thermalizing structure arranged to be in thermal contact with the gas and adapted to thermalize the gas to attain thermal equilibrium with the droplet generator before the gas is introduced into the gas acceleration zone.
11. A droplet generator as in clause 10 wherein the thermalizing structure is adapted to heat the gas to a temperature between 200° C. and 300° C.
12. A droplet generator as in clause 10 wherein the droplet generator further comprises a source material heater arranged to supply heat to the source material in the droplet generator and the thermalizing structure is arranged transfer heat between the source material heater and the gas.
13. A droplet generator as in clause 1 wherein the gas is a gas having a low EUV absorption.
14. A droplet generator as in clause 13 wherein the gas comprises hydrogen.
15. A droplet generator as in clause 1 wherein at least one of the first structure and second structure comprises a refractory metal.
16. A droplet generator as in clause 15 wherein the at least one of the first structure and second structure comprises molybdenum, tungsten, tantalum, rhenium, or an alloy of molybdenum, tungsten, tantalum, or rhenium.
17. A droplet generator as in clause 1 wherein the at least one of the first structure and second structure comprises a boron nitride coating.
18. A droplet generator as in clause 1 further comprising a flow management element positioned downstream of the second location and adapted to manage high velocity gas exiting the gas acceleration zone.
19. A method of accelerating droplets of EUV source material, the method comprising:
emitting a stream of liquid EUV source material from a nozzle outlet of a droplet generator;
transforming the stream of liquid EUV source material into a stream of coalesced droplets in a first structure defining a droplet coalescence zone, extending downstream from the nozzle outlet to a first location;
introducing the stream of coalesced droplets at the first location into a second structure defining a gas acceleration zone extending downstream from the first location to a second location;
introducing a flow of gas into the gas acceleration zone to flow streamwise substantially parallel to the stream of coalesced droplets;
accelerating the flow of gas in the gas acceleration zone as the gas approaches the second location;
and
entraining the coalesced droplets in the flow of gas to accelerate the coalesced droplets,
the droplet coalescence zone being arranged and configured such that liquid EUV source material in the droplet coalescence zone is not exposed to a streamwise flow of the gas.
20. A method as in clause 19 wherein a streamwise length of the droplet coalescence zone is between 10 mm and 200 mm.
21. A method as in clause 19 wherein a streamwise length of the droplet coalescence zone is between 20 mm and 100 mm.
22. A method as in clause 19 wherein the gas acceleration zone has a round cross section having a cross-sectional area that decreases between the first location and the second location.
23. A method as in clause 22 wherein the gas acceleration zone has a circular cross section having a radius that decreases between the first location and the second location.
24. A method as in clause 19 wherein accelerating the flow of gas in the gas acceleration zone comprises accelerating the gas so that a streamwise velocity of the gas does not exceed the speed of sound for the gas.
25. A method as in clause 19 wherein accelerating the flow of gas in the gas acceleration zone comprises accelerating the gas so that a streamwise velocity of the gas at the second location is approximately but less than the speed of sound for the gas.
26. A method as in clause 19 wherein introducing a flow of gas into the gas acceleration zone comprises introducing the gas so that a streamwise velocity of the gas at the first location is approximately equal to a streamwise velocity of the coalesced droplets leaving the droplet coalescence zone at the first location.
27. A method as in clause 19 wherein entraining the coalesced droplets in the flow of gas to accelerate the coalesced droplets accelerates the coalesced droplets gas such that coalesced droplets entering the gas acceleration zone at the first location accelerate while traversing the gas acceleration zone from about 80 m/sec to about 130 m/sec at the second location.
28. A method as in clause 19 further comprising thermalizing the gas to attain thermal equilibrium with the droplet generator before the gas is introduced into the gas acceleration zone.
29. A method as in clause 19 wherein thermalizing the gas comprises heating the gas to a temperature between 200° C. and 300° C.
30. A method as in clause 19 wherein the droplet generator comprises a source material heater arranged to supply heat to the source material in the droplet generator and thermalizing the gas comprises transferring heat between the source material heater and the gas.
31. A method as in clause 19 wherein the gas has a low EUV absorption.
32. A method as in clause 19 wherein the gas comprises hydrogen.
33. A method as in clause 19 wherein at least one of the first structure and second structure comprises a refractory metal.
34. A method as in clause 33 wherein the at least one of the first structure and second structure comprises at least one of molybdenum, tungsten, tantalum, and rhenium.
35. A method as in clause 19 wherein the at least one of the first structure and second structure comprises a boron nitride coating.
36. A droplet generator for generating a stream of droplets of EUV source material, the droplet generator comprising:
a nozzle adapted to emit liquid EUV source material from a nozzle outlet;
at least one inlet adapted to be connected to a source of a gas;
a first structure defining a first zone, extending downstream from the nozzle outlet to a first location, in which the liquid EUV source material emitted by the nozzle is not exposed to a flow of the gas, the EUV source material being in the form of a stream of droplets at the first location; and
a second structure defining a gas acceleration zone, extending downstream from the first location to a second location, in fluid communication with the inlet, arranged to receive the stream of droplets at the first location, and adapted to cause the gas to be introduced into the gas acceleration zone downstream of the first location and to accelerate and flow streamwise substantially parallel to the stream of droplets to entrain the droplets.
37. A droplet generator as in clause 36 further comprising a flow management element positioned downstream of the second location and adapted to manage high velocity gas exiting the gas acceleration zone.
38. A method of accelerating droplets of EUV source material, the method comprising:
emitting liquid EUV source material from a nozzle outlet of a droplet generator;
passing the liquid EUV source material through a first zone extending downstream from the nozzle outlet to a first location; the liquid EUV source material exiting the first zone as a stream of droplets;
introducing the stream of droplets at the first location into a gas acceleration zone extending downstream from the first location to a second location;
introducing a flow of gas into the gas acceleration zone to flow streamwise substantially parallel to the stream of droplets;
accelerating the flow of gas in the gas acceleration zone as the gas approaches the second location;
and
entraining the droplets in the flow of gas to accelerate the droplets,
the first zone being arranged and configured such that liquid EUV source material in the first zone is not exposed to a streamwise flow of the gas.

Other implementations are within the scope of the claims.

1. A droplet generator for generating a stream of droplets of EUV source material, the droplet generator comprising:
a nozzle adapted to emit a stream of liquid EUV source material from a nozzle outlet;
a first structure defining a droplet coalescence zone, extending downstream from the nozzle outlet to a first location, in which the stream of liquid EUV source material breaks up and coalesces into a stream of coalesced droplets of liquid EUV source material;
at least one inlet adapted to be connected to a source of a gas; and
a second structure defining a gas acceleration zone, extending downstream from the first location to a second location, in fluid communication with the at least one inlet, arranged to receive the stream of coalesced droplets at the first location, and adapted to cause the gas to be introduced into the gas acceleration zone downstream of the first location and to accelerate and flow streamwise substantially parallel to the stream of coalesced droplets to entrain the coalesced droplets,
the droplet coalescence zone being arranged and configured such that liquid EUV source material in the droplet coalescence zone is not exposed to a streamwise flow of the gas.

2. The droplet generator as in claim 1 wherein a streamwise length of the droplet coalescence zone is between 10 mm and 200 mm.

3. The droplet generator as in claim 2 wherein a streamwise length of the gas acceleration zone is between 20 mm and 200 mm.

4. The droplet generator as in claim 1 wherein the gas acceleration zone has a round cross section having a cross-sectional area that decreases between the first location and the second location.

5. The droplet generator as in claim 1 wherein the gas acceleration zone has a circular cross section having a radius that decreases between the first location and the second location.

6. The droplet generator as in claim 1 wherein the gas acceleration zone is configured so that a streamwise velocity of the gas does not exceed the speed of sound for the gas.

7. The droplet generator as in claim 1 wherein the gas acceleration zone is configured so that a streamwise velocity of the gas at the second location is approximately but less than the speed of sound for the gas.

8. The droplet generator as in claim 1 wherein the gas acceleration zone is configured so that a streamwise velocity of the gas at the first location is approximately equal to a streamwise velocity of the coalesced droplets leaving the droplet coalescence zone at the first location.

9. The droplet generator as in claim 1 wherein the gas accelerates the coalesced droplets gas such that coalesced droplets entering the gas acceleration zone at the first location accelerate from about 80 m/sec to about 130 m/sec while traversing the gas acceleration zone to the second location.

10. The droplet generator as in claim 1 further comprising a thermalizing structure arranged to be in thermal contact with the gas and adapted to thermalize the gas to attain thermal equilibrium with the droplet generator before the gas is introduced into the gas acceleration zone.

11. The droplet generator as in claim 10 wherein the thermalizing structure is adapted to heat the gas to a temperature between 200° C. and 300° C.

12. The droplet generator as in claim 10 wherein the droplet generator further comprises a source material heater arranged to supply heat to the source material in the droplet generator and the thermalizing structure is arranged transfer heat between the source material heater and the gas.

13. The droplet generator as in claim 1 wherein the gas is a gas having a low EUV absorption.

14. The droplet generator as in claim 13 wherein the gas comprises hydrogen.

15. The droplet generator as in claim 1 wherein at least one of the first structure and second structure comprises a refractory metal.

16. The droplet generator as in claim 15 wherein the at least one of the first structure and second structure comprises molybdenum, tungsten, tantalum, rhenium, or an alloy of molybdenum, tungsten, tantalum, or rhenium.

17. The droplet generator as in claim 1 wherein the at least one of the first structure and second structure comprises a boron nitride coating.

18. The droplet generator as in claim 1 further comprising a flow management element positioned downstream of the second location and adapted to manage high velocity gas exiting the gas acceleration zone.

19. A method of accelerating droplets of EUV source material, the method comprising:
emitting a stream of liquid EUV source material from a nozzle outlet of a droplet generator;
transforming the stream of liquid EUV source material into a stream of coalesced droplets in a first structure defining a droplet coalescence zone, extending downstream from the nozzle outlet to a first location;
introducing the stream of coalesced droplets at the first location into a second structure defining a gas acceleration zone extending downstream from the first location to a second location;
introducing a flow of gas into the gas acceleration zone to flow streamwise substantially parallel to the stream of coalesced droplets;
accelerating the flow of gas in the gas acceleration zone as the gas approaches the second location; and
entraining the coalesced droplets in the flow of gas to accelerate the coalesced droplets,
the droplet coalescence zone being arranged and configured such that liquid EUV source material in the droplet coalescence zone is not exposed to a streamwise flow of the gas.

20. The method as in claim 19 wherein a streamwise length of the droplet coalescence zone is between 10 mm and 200 mm.

21. The method as in claim 19 wherein a streamwise length of the droplet coalescence zone is between 20 mm and 100 mm.

22. The method as in claim 19 wherein the gas acceleration zone has a round cross section having a cross-sectional area that decreases between the first location and the second location.

23. The method as in claim 22 wherein the gas acceleration zone has a circular cross section having a radius that decreases between the first location and the second location.

24. The method as in claim 19 wherein accelerating the flow of gas in the gas acceleration zone comprises accelerating the gas so that a streamwise velocity of the gas does not exceed the speed of sound for the gas.

25. The method as in claim 19 wherein accelerating the flow of gas in the gas acceleration zone comprises accelerating the gas so that a streamwise velocity of the gas at the second location is approximately but less than the speed of sound for the gas.

26. The method as in claim 19 wherein introducing a flow of gas into the gas acceleration zone comprises introducing the gas so that a streamwise velocity of the gas at the first location is approximately equal to a streamwise velocity of the coalesced droplets leaving the droplet coalescence zone at the first location.

27. The method as in claim 19 wherein entraining the coalesced droplets in the flow of gas to accelerate the coalesced droplets accelerates the coalesced droplets gas such that coalesced droplets entering the gas acceleration zone at the first location accelerate while traversing the gas acceleration zone from about 80 m/sec to about 130 m/sec at the second location.

28. The method as in claim 19 further comprising thermalizing the gas to attain thermal equilibrium with the droplet generator before the gas is introduced into the gas acceleration zone.

29. The method as in claim 19 wherein thermalizing the gas comprises heating the gas to a temperature between 200° C. and 300° C.

30. The method as in claim 19 wherein the droplet generator comprises a source material heater arranged to supply heat to the source material in the droplet generator and thermalizing the gas comprises transferring heat between the source material heater and the gas.

31. The method as in claim 19 wherein the gas has a low EUV absorption.

32. The method as in claim 19 wherein the gas comprises hydrogen.

33. The method as in claim 19 wherein at least one of the first structure and second structure comprises a refractory metal.

34. The method as in claim 33 wherein the at least one of the first structure and second structure comprises at least one of molybdenum, tungsten, tantalum, and rhenium.

35. The method as in claim 19 wherein the at least one of the first structure and second structure comprises a boron nitride coating.

36. A droplet generator for generating a stream of droplets of EUV source material, the droplet generator comprising:
a nozzle adapted to emit liquid EUV source material from a nozzle outlet;
at least one inlet adapted to be connected to a source of a gas;
a first structure defining a first zone, extending downstream from the nozzle outlet to a first location, in which the liquid EUV source material emitted by the nozzle is not exposed to a flow of the gas, the EUV source material being in the form of a stream of droplets at the first location; and
a second structure defining a gas acceleration zone, extending downstream from the first location to a second location, in fluid communication with the inlet, arranged to receive the stream of droplets at the first location, and adapted to cause the gas to be introduced into the gas acceleration zone downstream of the first location and to accelerate and flow streamwise substantially parallel to the stream of droplets to entrain the droplets.

37. The droplet generator as in claim 36 further comprising a flow management element positioned downstream of the second location and adapted to manage high velocity gas exiting the gas acceleration zone.

38. A method of accelerating droplets of EUV source material, the method comprising:
emitting liquid EUV source material from a nozzle outlet of a droplet generator;
passing the liquid EUV source material through a first zone extending downstream from the nozzle outlet to a first location; the liquid EUV source material exiting the first zone as a stream of droplets;
introducing the stream of droplets at the first location into a gas acceleration zone extending downstream from the first location to a second location;
introducing a flow of gas into the gas acceleration zone to flow streamwise substantially parallel to the stream of droplets;
accelerating the flow of gas in the gas acceleration zone as the gas approaches the second location; and
entraining the droplets in the flow of gas to accelerate the droplets,
the first zone being arranged and configured such that liquid EUV source material in the first zone is not exposed to a streamwise flow of the gas.
